(19) United States
(12) Patent Application Publication
(10) Pub. No.: US 2018/0366368 A1
(43) Pub. Date: Dec. 20, 2018

(54) METHOD FOR FORMING CONTACT STRUCTURE

(71) Applicant: UNITED MICROELECTRONICS CORP., Hsin-chu City (TW)

(72) Inventors: Chun-Chieh Chiu, Keelung City (TW); Wei-Chuan Tsai, Changhua County (TW); Yen-Tsai Yi, Tainan City (TW); Li-Han Chen, Tainan City (TW)

(21) Appl. No.: 15/626,168

(22) Filed: Jun. 18, 2017

(51) Int. Cl. H01L 21/768; H01L 23/532; H01L 23/535

(52) U.S. Cl. CPC H01L 21/76829; H01L 21/76805; H01L 21/76864; H01L 21/76846; H01L 23/535; H01L 21/76895; H01L 21/7684; H01L 23/53266; H01L 21/76889

(57) ABSTRACT

The present invention provides a method for forming a contact structure, the method includes proving a substrate. An oxygen-containing dielectric layer is formed on the substrate. Next, a non-oxygen layer is formed on the oxygen-containing dielectric layer and a contact hole is then formed in the oxygen-containing dielectric layer. A metal layer is then formed in the contact hole and on the non-oxygen layer, with the non-oxygen layer disposed between the oxygen-containing dielectric layer and the metal layer. An anneal process is then performed to the metal layer, and a conductive layer is filled in the contact hole.

### BACKGROUND OF THE INVENTION

### 1. Field of the Invention

The present invention generally relates to semiconductor technology. More particularly, the invention relates to a method for improving the quality of a contact structure.

### 2. Description of the Prior Art

Field effect transistors are important electronic devices in the fabrication of integrated circuits, and as the size of the semiconductor device becomes smaller and smaller, the fabrication of the transistors also improves and is constantly enhanced for fabricating transistors with smaller sizes and higher quality. In the conventional method of fabricating transistors, a gate structure is first formed on a substrate, and a lightly doped drain (LDD) is formed on the two corresponding sides of the gate structure. Next, a spacer is formed on the sidewall of the gate structure and an ion implantation process is performed to form a source/drain region within the substrate by utilizing the gate structure and spacer as a mask. In order to incorporate the gate, source, and drain into the circuit, contact plugs are utilized for interconnection purposes. Each of the contact plugs include a barrier layer surrounding a low resistivity material to prevent the low resistivity material from diffusing outward to other areas. As the miniaturization of semiconductor devices increases, filling the barrier layer and the low resistivity into a contact hole has become an important issue to form the contact plug and maintaining or enhancing the performances of formed semiconductor devices as well.

### SUMMARY OF THE INVENTION

The present invention provides a method for forming a contact structure, the method comprising: first, a substrate is provided, an oxygen-containing dielectric layer is formed on the substrate, next, a non-oxygen layer is formed on the oxygen-containing dielectric layer, and a contact hole is then formed in the oxygen-containing dielectric layer, afterwards, a metal layer is formed in the contact hole and on the non-oxygen layer, wherein the non-oxygen layer is disposed between the oxygen-containing dielectric layer and the metal layer, an anneal process is then performed to the metal layer, and a conductive layer is filled in the contact hole.

One feature of the present invention is that the non-oxygen layer is formed before the contact hole is formed and the metal layer is then filled in the contact hole. Therefore, a metal oxide layer is only formed in the contact hole, but not disposed on the top surface of the oxygen-containing dielectric layer. In this way, the metal oxide layer does not contact the top surface of the oxygen-containing dielectric layer directly. By the applicant's experiment, the non-oxygen layer is more difficult to be peeled off from the oxygen-containing dielectric layer than the metal oxide layer is. Therefore, after a planarization process is performed, the conductive layer loss from the contact hole issue can be prevented, and thereby improving the reliability of the contact structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic diagrams showing a method for fabricating a contact structure according to one embodiment of the invention, wherein FIGS. 2-6 show the partial enlarged diagrams of the semiconductor device according to one embodiment of the present invention.

FIG. 7 shows a partial enlarged schematic diagram of the semiconductor device while the planarization process is performed according to one embodiment of the present invention.

FIG. 8 shows a partial enlarged schematic diagram of the semiconductor device while the planarization process is performed according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

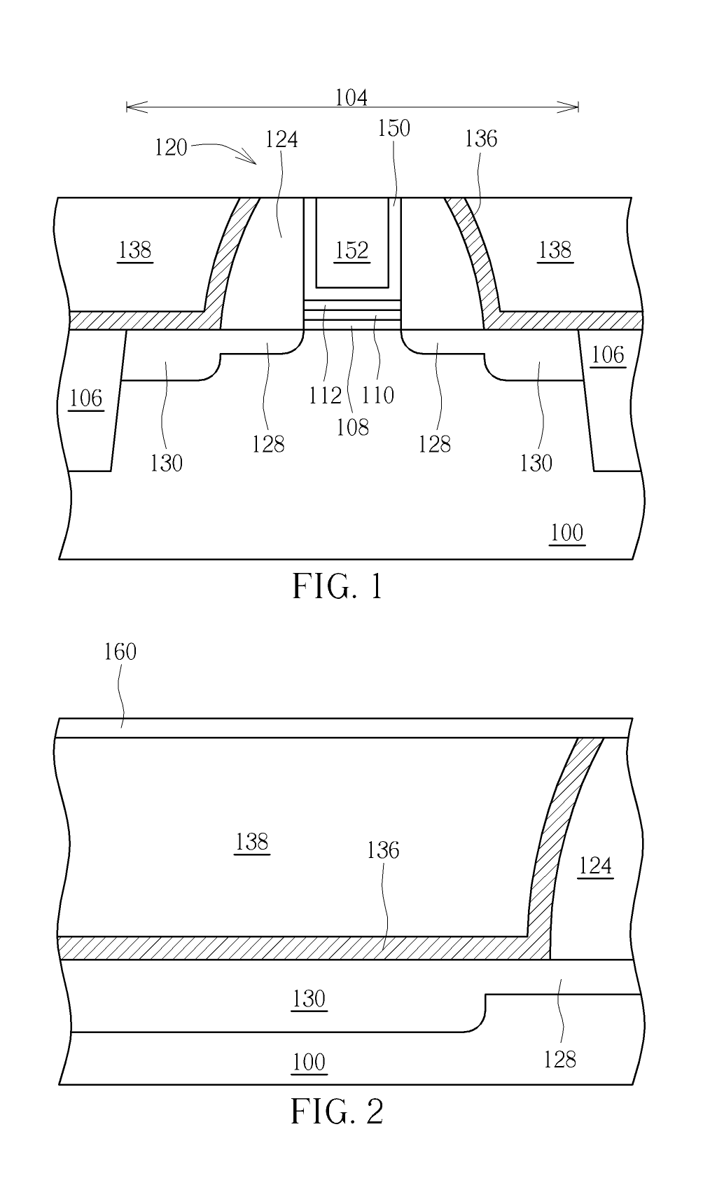

FIGS. 1-6 are schematic diagrams showing a method for fabricating a contact structure according to one embodiment of the invention. The contact structure of the present invention should be formed in a semiconductor device. Generally speaking, a substrate is provided, having a dielectric layer disposed thereon. In the present invention, the dielectric layer may include a material such as silicon dioxide. At least one semiconductor device, which including the source/drain regions and the metal gate or polysilicon gate, is formed in the substrate and the dielectric layer, and the contact structure is then formed in the dielectric layer. More precisely, as shown in FIG. 1, a semiconductor device is provided first, for example, a complementary metal oxide semiconductor transistor (CMOS), which is fabricated through a gate-last process accompanied with a high-k first process. A structure of which is described as follows. A substrate 100, such as a silicon substrate, a silicon-on-insulator (SOI) or the like is provided. In one embodiment of the present invention, at least one fin structure (not shown) can be formed on the substrate, but not limited thereto. A transistor region 104 is defined on the substrate 100, the transistor region 104 may be an NMOS region or a PMOS region. A plurality of shallow trench isolations (STI) 106 is formed in the substrate 100 for separating different transistor regions (such as NMOS region and PMOS region). A gate structure 120 is formed on the transistor region 104. Each sidewall of the gate structure 120 has at least a spacer, such as a first spacer 124. A lightly doped region 128 is disposed in the substrate 100 below the first spacer 124. At least a source/drain region 130 are disposed between the shallow trench isolations 106, and the source/drain region 130 is not covered by the first spacer 124. It is worth noting that an epitaxial layer (not shown) may be additionally formed in the source/drain region 130 within each transistor region 104 to thereby adjust carrier mobility in the CMOS device. In this embodiment, the epitaxial layer is fabricated in the substrate 100 on each side of the first spacer 124 within the transistor region 104, wherein the epitaxial layer preferably includes germanium silicon, silicon carbide (SiC), phosphorus silicide (SiP) and may have a single layer or a multiple layers structure. A cover layer 136 is formed on the substrate 100, which may cover the gate structure 120. The cover layer may be a contact etch stop layer (CESL) which has a suitable stress. Additionally, an inter layer dielectric (ILD) 138 is formed on the substrate 100 and covers transistor region 104. In the present invention, the ILD 138 preferably includes an oxygen-containing dielectric layer, such as borophosphosilicate glass (BPSG), borosilicate glass (BSG), phosphosilicate glass (PSG), silicon dioxide, or the like. Silicon dioxide is used as an example ILD 138 in the following paragraphs.

In this embodiment, the gate structure 120 is a kind of metal gate structure that includes a high-k dielectric layer 110, a work function layer 150 and a metal layer 152. According to another embodiment, a barrier layer 112 and a dielectric layer 108 may be formed on and below the high-k dielectric layer 110, respectively and the composition of which may be of dielectric materials, such as metal oxide or metal nitride. The barrier layer 112 may be located between the work function layer 150 and the metal layer 152 to prevent atoms from diffusing from the metal layer 152. In addition, the high-K dielectric layer 110 described above may include at least one of HfO₂, HfSiO₄, HfSiON, Al₂O₃, La₂O₃, Ta₂O₅, Y₂O₃, ZrO₂, SrTiO₃, ZrSiO₄, HfZrO₄, strontium bismuth tantalate (SBT), lead zirconate titanate (PZT), or barium strontium titanate (BST), but is not limited thereto.

According to the preceding paragraph, a CMOS, fabricated through gate-last processes is provided, which is not the only kind of semiconductor device suitable for the invention. The semiconductor device may also be a CMOS with polysilicon gate or a CMOS fabricated through gate-first processes. It should also be within the scope of the present invention.

Afterwards, the specific technique features according to the invention will be described clearly in the following sequences. It is noteworthy that from FIG. 2 to the following paragraphs, in order to simplify the figure, only the region that is near one source/drain region and the ILD is shown in figures. Other components such as the gate structure and the STI are omitted.

FIGS. 2-6 show the partial enlarged diagram of the semiconductor device according to one embodiment of the present invention. As shown in FIG. 2, a non-oxygen layer 160, such as an amorphous silicon layer, a SiN layer, a SiC layer or a SiCN layer is formed on and directly contacts the ILD 138 (the oxygen-containing dielectric layer). In this embodiment, the non-oxygen layer 160 is an amorphous silicon layer. The thickness of the non-oxygen layer 160 is preferably between 30 angstroms to 70 angstroms, but not limited thereto. The purpose for forming the non-oxygen layer 160 on the oxygen-containing dielectric layer is to prevent a metal oxide layer from being formed between the oxygen-containing dielectric layer and the following-formed metal layer. In other words, in the following steps, a metal layer will be formed on the ILD 138, and the non-oxygen layer 160 is formed before the metal layer, so the non-oxygen layer 160 is disposed between the flowing-formed metal layer and the ILD 138. If the non-oxygen layer 160 is omitted, a metal oxide layer (not shown) may be formed between the metal layer and the ILD 138, it will influence the quality of the contact structure. The feature mentioned above will be described more detail in the following paragraphs.

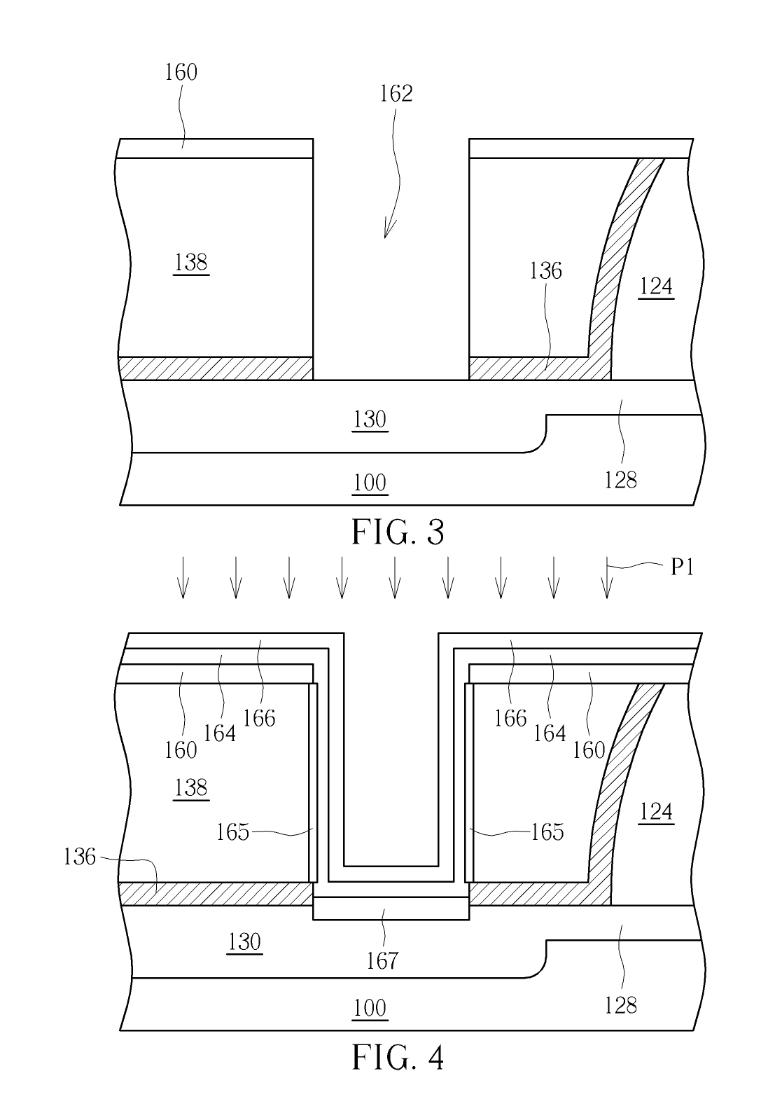

Next, as shown in FIG. 3, at least a contact hole 162 is formed inside the ILD 138 to expose a related silicon region. In this case, the silicon region refers to source/drain region 130. According to another embodiment, the silicon region may refer to any semiconductor region exposed by the contact hole 162. For example, the semiconductor region may be doped or un-doped monocrystalline silicon or polycrystalline silicon, wherein dopants include phosphor, arsenic, boron, germanium or a combination of which, but are not limited to. It is noteworthy that the non-oxygen layer 160 is formed before the contact hole 162 is formed, so the non-oxygen layer 160 is only disposed on the ILD 138, but not disposed in the contact hole 162.

Please refer to FIGS. 4-6, as shown in FIG. 4, a metal layer 164 and a barrier layer 166 are formed, the metal layer 164 may include materials such as a titanium layer, the barrier layer 166 being materials such a titanium nitride (TiN) layer or a tantalum nitride (TaN). The metal layer 164 and the barrier layer 166 are formed on the top surface of the non-oxygen layer 160 and in the contact hole 162. It is noteworthy that after the metal layer 164 is formed, a anneal process P1 is then performed to form a silicide region 167 in the contact hole 162. Besides, in the contact hole 162, a metal oxide layer 165 (such as a titanium dioxide, TiO₂) will be formed at the interface between the inner surface of the contact hole 162 (the material being such as silicon dioxide) and the metal layer 164 (the material being such as titanium) . However, since the non-oxygen layer 160 on the top surface of the ILD 138 isolates the ILD 138 (the material being such as silicon dioxide) from the metal layer 164, a metal oxide layer 165 will not be formed between the ILD 138 and the metal layer 164 on the top surface of the ILD 138. More precisely, the metal layer 164 is formed on the non-oxygen layer 160 and in the contact hole 162, but the metal oxide layer 165 is only formed in the contact hole 162, disposed along the inner sidewall of the contact hole 162, but not disposed on the top surface of the ILD 138.

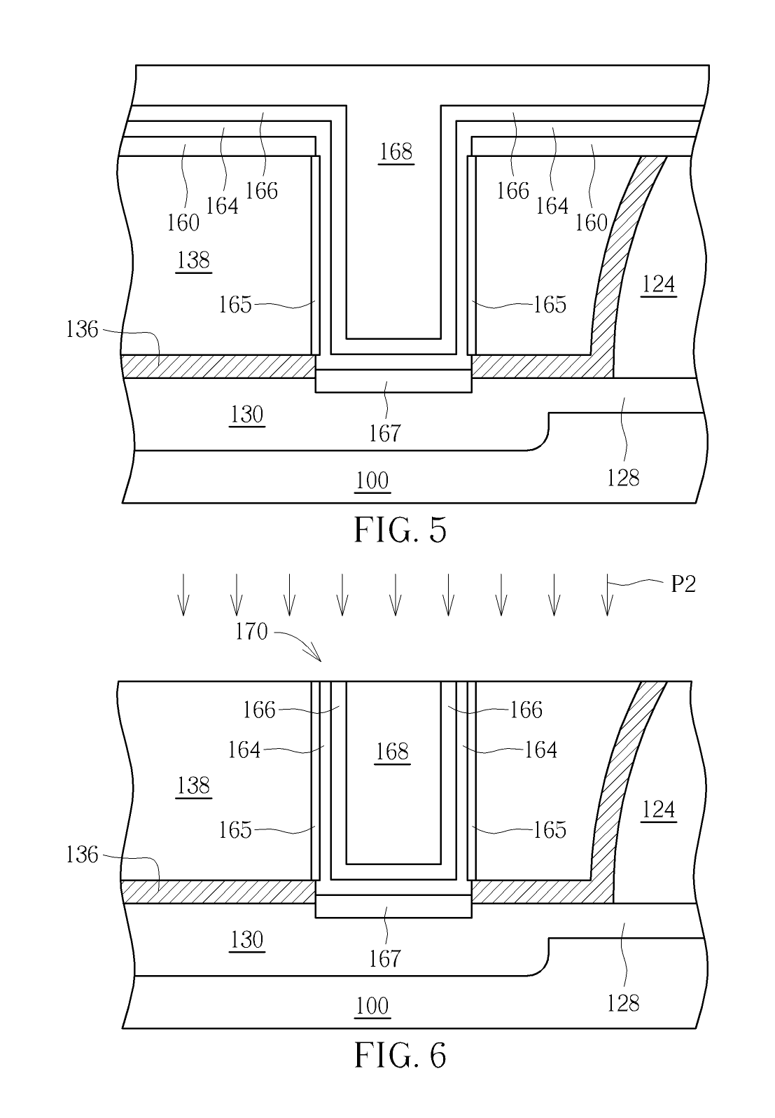

Next, as shown in FIG. 5, a conductive layer 168 is then filled in the contact hole 162, the conductive layer 168 being materials such a tungsten (W) layer, but not limited thereto. Afterwards, as shown in FIG. 6, a planarization process P2, such as a chemical mechanical polishing (CMP), is performed to remove the extra conductive layer 168, the barrier layer 166, the metal layer 164 and the non-oxygen layer 160, until the top surface of the ILD 138 is exposed. In this step, the contact structure 170 has been completed.

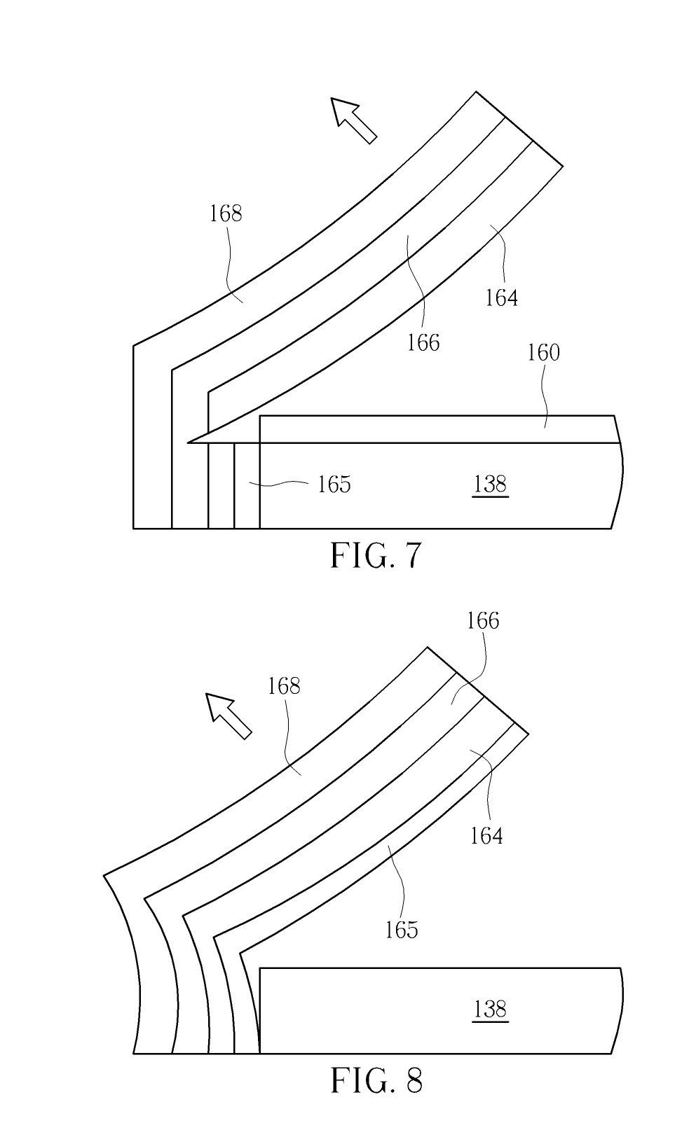

Please refer to FIG. 7, which shows a partial enlarged schematic diagram of the semiconductor device during the planarization process is performed according to the first preferred embodiment of the present invention mentioned above. An enlarged region near the upper corner of the contact hole 162 is shown in FIG. 7. As shown in FIG. 7, one feature of the present invention is that the non-oxygen layer 160 is formed before the contact hole 162 is formed, and the metal layer 164 is then filled in the contact hole 162. Therefore, the metal oxide layer 165 is only formed in the contact hole 162, but not disposed on the top surface of the oxygen-containing dielectric layer (ILD 138). In this way, the metal oxide layer 165 does not contact the top surface of the oxygen-containing dielectric layer 138 directly. By the applicant's experiment, the non-oxygen layer 160 is more difficult to be peeled off from the oxygen-containing dielectric layer 138 than the metal oxide layer 165 is. Therefore, after a planarization process is performed, the conductive layer loss from the contact hole issue can be prevented, and thereby improving the reliability of the contact structure.

To compare with the first preferred embodiment, please refer to FIG. 8, which shows a partial enlarged schematic diagram of the semiconductor device while the planarization process is performed according to another embodiment of the present invention. In this embodiment, the non-oxygen layer 160 mentioned above is omitted, so the metal oxide layer 165 is formed in the contact hole 162 and also be formed on the top surface of the ILD 138, for example, the metal oxide layer 165 has an inverted L shaped profile shown in FIG. 7. By the applicant's experiment, the metal oxide layer 165 is easily to “peel off” from the ILD 138. Therefore, the conformal metal oxide layer 165 maybe removed accompanied with other layers disposed on the metal oxide layer 165 (such as the barrier layer 166 and the conductive layer 168) during the planarization process P2, and cause the conductive layer 168 partially loss from the contact hole 162, and may influence the quality of the contact structure.

Those skilled in the art will readily observe that numerous modifications and alterations of the device and method may be made while retaining the teachings of the invention. Accordingly, the above disclosure should be construed as limited only by the metes and bounds of the appended claims.

1. A method for forming a contact structure, comprising:
providing a substrate;
forming an oxygen-containing dielectric layer on the substrate;
forming a non-oxygen layer on the oxygen-containing dielectric layer;
forming a contact hole in the oxygen-containing dielectric layer;
forming a metal layer in the contact hole and on the non-oxygen layer, wherein the non-oxygen layer is disposed between the oxygen-containing dielectric layer and the metal layer;
performing an anneal process to the metal layer, wherein during the anneal process, parts of the metal layer is transferred into a metal oxide layer, and wherein the metal oxide layer is disposed along the inner sidewalls of the contact hole in the edge of the oxygen-containing dielectric layer facing the metal layer; and
filling a conductive layer in the contact hole.

2. (canceled)

3. The method of claim 1, wherein the metal oxide layer does not contact a top surface of the oxygen-containing dielectric layer directly.

4. The method of claim 1, wherein the oxygen-containing dielectric layer comprises a silicon dioxide layer.

5. The method of claim 1, further comprising forming a barrier layer on the metal layer before the conductive layer is formed.

6. The method of claim 5, wherein the barrier layer comprises a TiN layer or a TaN layer.

7. The method of claim 1, wherein the conductive layer comprises a tungsten layer.

8. The method of claim 1, wherein after the conductive layer is formed, further comprising performing a planarization process to the conductive layer and the metal layer, so as to remove parts of the conductive layer and completely remove the metal layer.

9. The method of claim 1, wherein the non-oxygen layer comprises an amorphous silicon layer, a SiN layer, a SiC layer or a SiCN layer.

10. The method of claim 1, wherein a thickness of the non-oxygen layer is between 30 angstroms to 70 angstroms.

11. The method of claim 1, wherein the metal layer comprises a titanium layer.
